(19) United States
(12) Patent Application Publication
(10) Pub. No.: US 2026/0060088 A1
(43) Pub. Date: Feb. 26, 2026

(54) POWER MODULE

(71) Applicant: Advanced Semiconductor Engineering, Inc., Kaohsiung (TW)

(72) Inventors: Yuhsien CHIEN, Kaohsiung (TW); Chiawei LIN, Kaohsiung (TW); Peinung WU, Kaohsiung (TW); Chingyao HSU, Kaohsiung (TW); Jenchun CHEN, Kaohsiung (TW)

(73) Assignee: Advanced Semiconductor Engineering, Inc., Kaohsiung (TW)

(21) Appl. No.: 18/814,450

(22) Filed: Aug. 23, 2024

(51) Int. Cl. H01L 23/00; H01L 23/31; H01L 23/367; H01L 23/433

(52) U.S. Cl. CPC H01L 23/562; H01L 23/3157; H01L 23/3675; H01L 23/4334

(57) ABSTRACT

The present disclosure relates to a power module. The power module includes a first die having an upper surface; a second die adjacent to the first die and having an upper surface at an elevation different from the upper surface of the first die; a circuit structure disposed over the first die and the second die and having a surface; and an elastic structure connecting the first die and the second die to the first circuit structure and configured to keep the surface of the circuit structure being substantially horizontal.

### BACKGROUND

### 1. Technical Field

The present disclosure generally relates to a power module, and more particularly to a power module including elastic structures stacked on power dies.

### 2. Description of the Related Art

As power modules are required to supply higher power to fulfill higher charge rates, and heat dissipation becomes more challenging. Currently, power modules may have a double-sided cooling arrangement. Between the two side cooling elements, the power module includes multiple stacked elements. In such case, the total height of the power modules is difficult to contain due to accumulated tolerance of the multilayered structure. Therefore, an improved power module is needed.

### SUMMARY

In some embodiments, a power module includes a first die having an upper surface; a second die adjacent to the first die and having an upper surface at an elevation different from the upper surface of the first die; a circuit structure disposed over the first die and the second die and having a surface; and an elastic structure connecting the first die and the second die to the first circuit structure and configured to keep the surface of the circuit structure being substantially horizontal.

In some embodiments, a power module includes a first power die; a first circuit structure disposed over the first power die and configured to provide a thermal dissipated channel for the first power die; and a first elastic structure electrically connecting the first power die to the first circuit structure and including an housing and an elastic element within the housing.

In some embodiments, a power module includes a first power die; a second power die beside the first power die; a first circuit layer disposed on the first power die and the second power die; a first elastic structure disposed between the first circuit layer and the first power die, wherein the first elastic structure has a first elastic modulus; and a second elastic structure disposed between the first circuit layer and the second power die, wherein the second elastic structure has a second elastic modulus different from the first elastic modulus.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 is a cross-section of a power module, in accordance with some embodiments of the present disclosure.

FIG. 2A is a schematic diagram of an elastic structure, in accordance with some embodiments of the present disclosure.

FIG. 2B is a schematic diagram of an elastic structure, in accordance with some embodiments of the present disclosure.

FIG. 2C(a) is a schematic diagram of an elastic structure, in accordance with some embodiments of the present disclosure.

FIG. 2C(b) is a cross-section of the elastic structure of FIG. 2C(a), in accordance with some embodiments of the present disclosure.

FIG. 3A is a bottom view of a circuit layer of a power module, in accordance with some embodiments of the present disclosure.

FIG. 3B is a top view of a circuit layer of a power module, in accordance with some embodiments of the present disclosure.

FIG. 4A, FIG. 4B, FIG. 4C, and FIG. 4D illustrate one or more operations of a method for manufacturing a power module, in accordance with some embodiments of the present disclosure.

FIG. 5A, FIG. 5B, FIG. 5C, and FIG. 5D illustrate one or more operations of a method for manufacturing a power module, in accordance with some embodiments of the present disclosure.

FIG. 6A, FIG. 6B, and FIG. 6C illustrate one or more operations of a method for manufacturing a power module, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

The total size of power modules and tolerance accumulation issue thereof may be solved by a power module with elastic structure. The elastic structure can provide flexibility to adjust total height of the power module during molding processes. Therefore, after molding, the power module can present a controlled height. The elastic structure may further provide electric conductivity, thermal conductivity, and support for other elements.

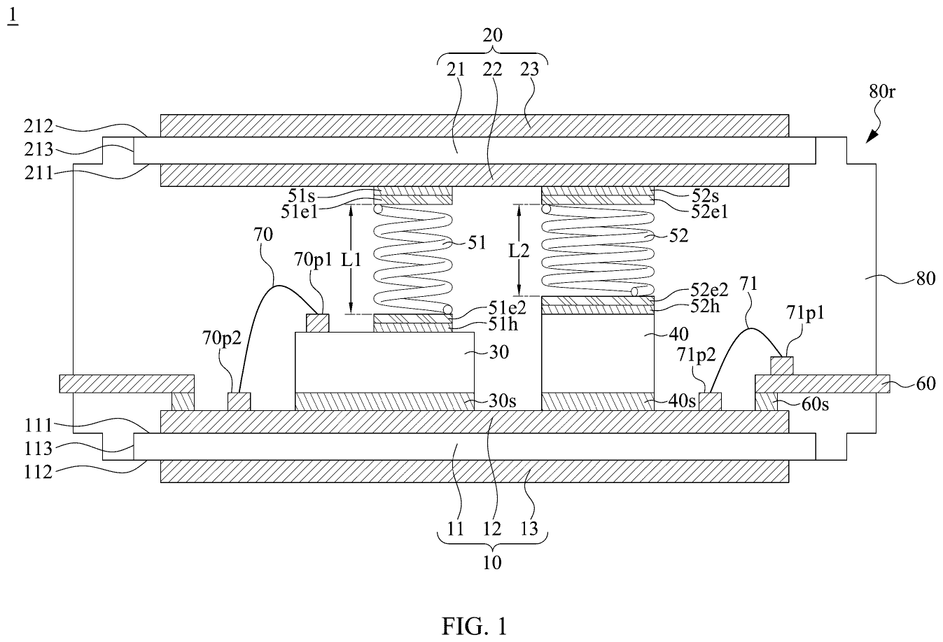

FIG. 1 is a cross-section of a power module 1, in accordance with some embodiments of the present disclosure. The power module 1 may include circuit layers 10 and 20, dies 30 and 40, elastic structures 51 and 52, one or more leadframes 60, one or more conductive wires 70 and 71, and an encapsulant 80.

Referring to FIG. 1, the circuit layer 10 may include a core substrate 11 and two conductive layers 12 and 13. The core substrate 11 may have a first surface 111 and a second surface 112 opposite to the first surface 111. The conductive layer 12 may be disposed on the first surface 111 of the core substrate 11. The conductive layer 12 may be patterned. The patterned conductive layer 12 may be configured to provide electrical connection. In some embodiments, the conductive layer 13 may be disposed on the second surface 112 of the core substrate 11. The conductive layer 13 may be pattern-free. That is, the conductive layer 13 may be a conductive plate without any patterns. For example, the conductive layer 13 may be a square plate. In other embodiments, the conductive layer 13 may be any suitable shapes.

In some embodiments, the core substrate 11 may be disposed between the conductive layers 12 and 13. The width of the core substrate 11 may be greater than or equal to the width of the conductive layers 12 and 13. In some embodiments, the width of the conductive layer 12 may be substantially identical to that of the conductive layer 13.

In some embodiments, the core substrate 11 may be a dielectric layer. For example, the core substrate 11 may include a ceramic material. In some embodiments, the conductive layers 12 and 13 may include a conductive material such as a metal or metal alloy. Examples of the conductive material include aluminum (Al), copper (Cu), or an alloy thereof. The circuit layer 10 may be a circuit structure. In some embodiments, the circuit layer 10 may be a direct bonded copper (DBC) substrate or an active metal brazed (AMB) substrate. In some embodiments, the circuit layer 10 can provide electrical conductivity with thermal dissipation.

In some embodiments, the circuit layer 20 may be disposed on the circuit layer 10. The circuit layer 20 may include a core substrate 21 and two conductive layers 22 and 23. The core substrate 21 may have a first surface 211 and a second surface 212 opposite to the first surface 211. The conductive layer 22 may be disposed on the first surface 211 of the core substrate 21. The conductive layer 22 may be patterned. The patterned conductive layer 22 may be configured to provide electrical connection. In some embodiments, the conductive layer 23 may be disposed on the second surface 212 of the core substrate 21. The conductive layer 23 may be free from pattern. That is, the conductive layer 23 may be a conductive plate without any patterns. For example, the conductive layer 23 may be a square plate. In other embodiments, the conductive layer 23 may be any suitable shapes.

In some embodiments, the core substrate 21 may be disposed between the conductive layers 22 and 23. The width of the core substrate 21 may be greater than or equal that of the conductive layers 22 and 23. In some embodiments, width of the conductive layer 22 may be substantially identical to that of the conductive layer 23.

In some embodiments, the core substrate 21 may be a dielectric layer. For example, the core substrate 21 may include a ceramic material. In some embodiments, the conductive layers 22 and 23 may include a conductive material such as a metal or metal alloy. Examples of the conductive material include aluminum (Al), copper (Cu), or an alloy thereof. The circuit layer 20 may be a circuit structure. In some embodiments, the circuit layer 20 may be a direct bonded copper (DBC) substrate or an active metal brazed (AMB) substrate. In some embodiments, the circuit layer 20 can provide electrical conductivity with thermal dissipation.

In some embodiments, the dies 30 and 40 may be disposed between the circuit layers 10 and 20. The dies 30 and 40 may be disposed on the circuit layer 10. For example, the dies 30 and 40 may be disposed on the patterned conductive layer 12. The die 30 may be disposed adjacent to or beside the die 40. In some embodiments, the die 30 may be spaced apart from the die 40 by a distance.

In some embodiments, the dies 30 and 40 may be electrically connected to the conductive layer 12 of the circuit layer 10. The die 30 may adhere and connect to the circuit layer 10 through a soldering material 30s. Similarly, the die 40 may adhere and connect to the circuit layer 10 through a soldering material 40s. In some embodiments, the solder materials 30s and 40s may be solder paste, solder bumps, or solder ball, or non-solder conductive structures such as copper pillar, or a combination thereof. In some embodiments, the heat generated by the dies 30 and 40 may be dissipated by the circuit layer 10. In some embodiments, a heatsink (not shown) may be disposed under the conductive layer 13 for dissipating heat from the dies 30 and 40. That is, the circuit layer 10 may be configured to establish a thermal dissipation path for the dies 30 and 40.

The thickness of die 30 may be different from that of die 40. For example, the thickness of the die 30 may be less than the thickness of the die 40. In some embodiments, the dies 30 and 40 may be power dies. The dies 30 and 40 may be a transistor or a diode. For example, the dies 30 and 40 may be an insulated gate bipolar transistor (IGBT). In some embodiments, one of the dies 30 and 40 may be a transistor, and another one may be a diode. For example, the die 30 may be a transistor and the die 40 may be a diode.

In some embodiments, the elastic structure 51 may be disposed on the die 30. The elastic structure 51 may be disposed between the die 30 and the circuit layer 20. The elastic structure 51 may electrically connect the die 30 to the circuit layer 20. In some embodiments, the elastic structure 51 may be configured to dissipate heat from the die 30. That is, a thermal dissipation path of the die 30 may be established through the elastic structure 51 to the circuit layer 20. In some embodiments, the elastic structure 51 may include a conductive material such as a metal or metal alloy. Examples of the conductive material include gold (Au), silver (Ag), aluminum (Al), copper (Cu), or an alloy thereof.

In some embodiments, the elastic structure 51 may include connectors 51e1 and 51e2 on two ends, respectively. The connectors 51e1 and 51e2 may be greater than the ends of the elastic structure 51, such that the elastic structure 51 could be easier to connect to the die or circuit layer. In some embodiments, the connectors 51e1 and 51e2 may include a pad, a conductive ball, or the like. The connectors 51e1 and 51e2 may be performed and then adhered to or connected to the elastic structure 51. In another embodiment, the connectors 51e1 and 51e2 may be formed together with the elastic structure 51. The connectors 51e1 and 51e2 may include a conductive material such as a metal or metal alloy. Examples of the conductive material include gold (Au), silver (Ag), aluminum (Al), copper (Cu), or an alloy thereof. In some embodiments, the connectors 51e1 and 51e2 may include a material substantially identical to the elastic structure 51.

The elastic structure 51 may adhere and connect to the die 30 through a soldering material 51h via the connector 51e1. In some embodiments, the elastic structure 51 may adhere and connect to the circuit layer 20, i.e., the conductive layer 22, through a soldering material 51s via the connector 51e2. In some embodiments, the solder materials 51h and 51s may be solder paste, solder bumps or solder ball, or non-solder conductive structures such as copper pillar, or a combination thereof.

In some embodiments, the elastic structure 52 may be disposed on the die 40. The elastic structure 52 may be disposed between the die 40 and the circuit layer 20. The elastic structure 52 may electrically connect the die 40 to the circuit layer 20. In some embodiments, the elastic structure 52 may be configured to dissipate heat from the die 40. That is, a thermal dissipation path of the die 40 may be established through the elastic structure 52 to the circuit layer 20. The elastic structure 52 may be similar to the elastic structure 51.

In some embodiments, the heat generated by the dies 30 and 40 may be dissipated through the elastic structures 51 and 52 to the circuit layer 20. In some embodiments, a heatsink (not shown) may be disposed under the conductive layer 23 for dissipating heat from the dies 30 and 40. That is, the circuit layer 20 may be configured to establish a thermal dissipation path for the dies 30 and 40.

In some embodiments, the elastic structure 52 may include connectors 52e1 and 52e2 on two ends, respectively. The connectors 52e1 and 52e2 may be greater than the ends of the elastic structure 52, such that the elastic structure 52 could be easier to connect to the die or circuit layer. In some embodiments, the connectors 52e1 and 52e2 may include a pad, a conductive ball, or the like. The connectors 52e1 and 52e2 may be performed and then adhered to or connected to the elastic structure 52. In another embodiment, the connectors 52e1 and 52e2 may be formed together with the elastic structure 52. The connectors 52e1 and 52e2 may include a conductive material such as a metal or metal alloy. Examples of the conductive material include gold (Au), silver (Ag), aluminum (Al), copper (Cu), or an alloy thereof. In some embodiments, the connectors 52e1 and 52e2 may include a material substantially identical to the elastic structure 52.

The elastic structure 52 may adhere and connect to the die 30 through a soldering material 52h via the connector 52e1. In some embodiments, the elastic structure 52 may adhere and connect to the circuit layer 20, i.e., the conductive layer 22, through a soldering material 52s via the connector 52e2. In some embodiments, the solder materials 52h and 52s may be solder paste, solder bumps or solder ball, or non-solder conductive structures such as copper pillar, or a combination thereof.

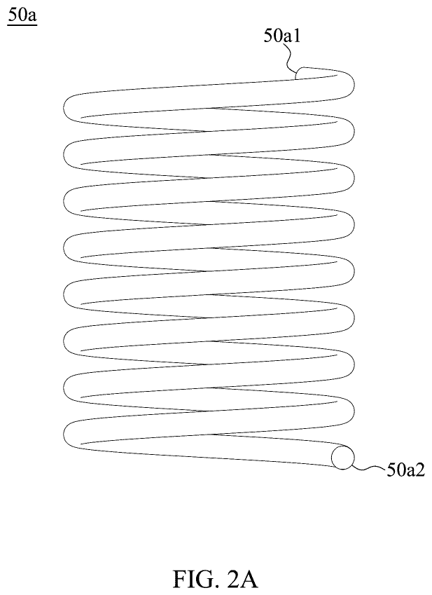

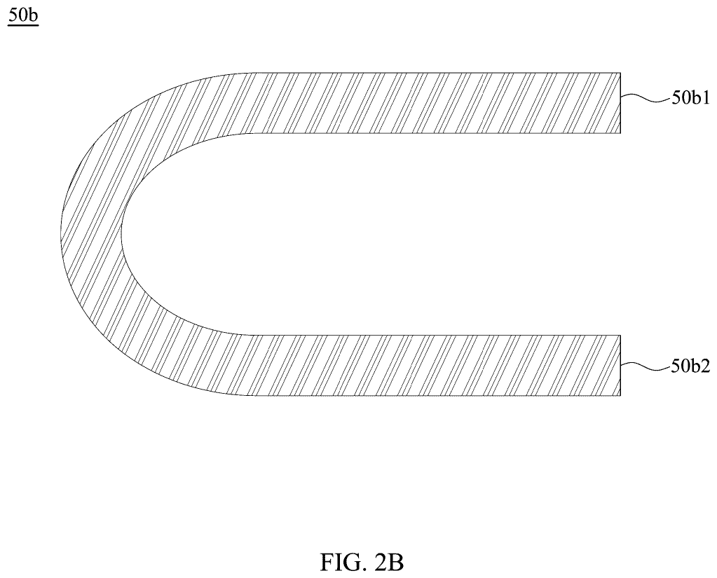

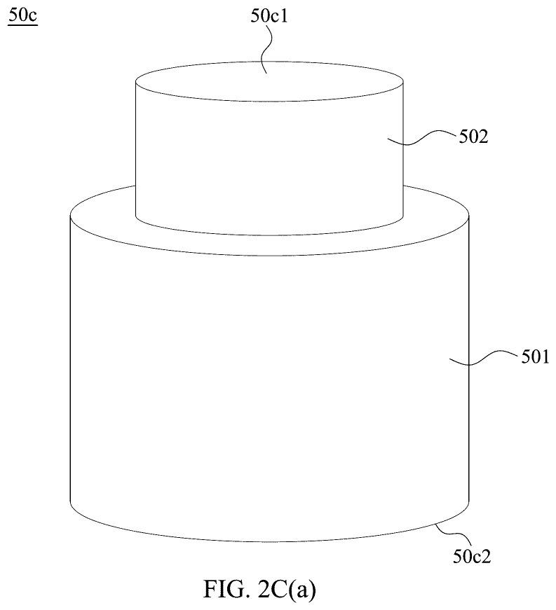

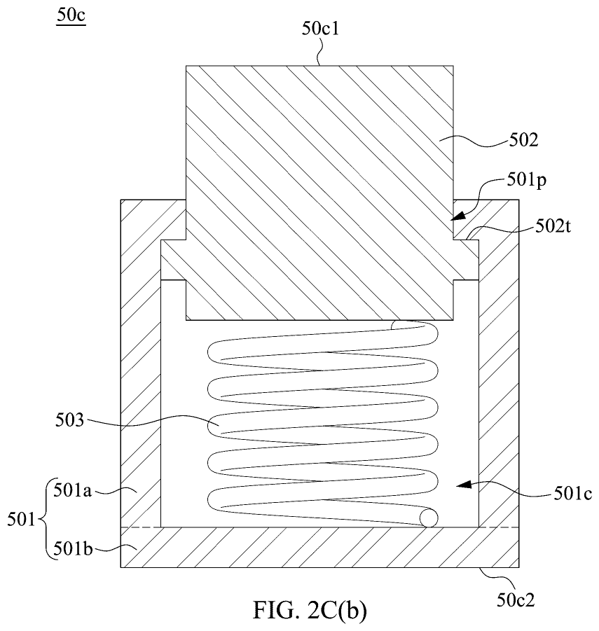

In some embodiments, the elastic structures 51 and 52 may be a buffer structure. In some embodiments, the elastic structures 51 and 52 may be a spring, an elastic reed, or an elastic barrel. In some embodiments, the elastic structures 51 and 52 may be the same type or different type. The elastic structure 51 may have a first elastic modulus and the elastic structure 52 may have a second elastic modulus different from the first elastic modulus. In some embodiments, the elastic modulus of the elastic structure may depend on the area connected to the dies. For example, the first elastic modulus of the elastic structure 51 may be less than the second elastic modulus of the elastic structure 52. That is, the elastic structure 51 could be more flexible and easier to compress, such that the force applied to the die 30 can be less. On the contrary, the elastic structure 52 could be harder to compress, such that the force applied to the die 40 can be greater. When no force is applied to the elastic structures 51 and 52, the initial lengths of the elastic structures 51 and 52 may be substantially identical or different. In some embodiments, a length L1 of the elastic structure 51 may be different from a length L2 of the elastic structure 52. For example, the length L1 of the elastic structure 51 may be greater than the length L2 of the elastic structure 52. In some embodiments, the elastic structures 51 and 52 may be configured to control a height of the power module 1. More embodiments of the elastic structures 51 and 52 can be found in FIG. 2A to FIG. 2C(b).

In some embodiments, one or more leadframes 60 may be disposed on the circuit layer 10. The leadframe 60 may adhere and connect to the circuit layer 10 through a soldering material 60s. In some embodiments, the solder material 60s may be solder paste, solder bumps or solder ball, or non-solder conductive structures such as copper pillar, or a combination thereof. The leadframe 60 may be electrically connected to the die 30 and/or die 40 through the circuit layer 10. The leadframe 60 may connect the dies 30 and 40 to the external components.

In some embodiments, one or more conductive wires 70 may connect the die 30 to the circuit layer 10. The power module 1 may include a conductive pad 70p1 disposed on the top surface of the die 30 and a conductive pad 70p2 disposed on the conductive layer 12 of the circuit layer 10. The conductive wire 70 may connect to the conductive pads 70p1 and 70p2. The conductive wire 70 may be bonded to the top surface of the die 30 through the conductive pad 70p1. The conductive wire 70 may be bonded to the top surface of the conductive layer 12 of the circuit layer 10 through the conductive pad 70p2. In some embodiments, the conductive pads 70p1 and 70p2 may be solder paste, solder bumps or solder ball, or non-solder conductive structures such as copper pillar, or a combination thereof.

In some embodiments, the die 30 may have two, three, or more terminals. One terminal of the die 30 may connect to a portion of the conductive layer 12, and another terminal of the die 30 may connect to another portion of the conductive layer 12 through the conductive wire 70.

In some embodiments, one or more conductive wires 71 may connect the leadframe 60 to the circuit layer 10. The power module 1 may include a conductive pad 71p1 disposed on the leadframe 60 and a conductive pad 71p2 disposed on the conductive layer 12 of the circuit layer 10. The conductive wire 71 may connect to the conductive pads 71p1 and 71p2. The conductive wire 71 may be bonded to the leadframe 60 through the conductive pad 71p1. The conductive wire 71 may be bonded to the top surface of the conductive layer 12 of the circuit layer 10 through the conductive pad 71p2. In some embodiments, the conductive pads 71p1 and 71p2 may be solder paste, solder bumps or solder ball, or non-solder conductive structures such as copper pillar, or a combination thereof. In other embodiments, the power module 1 may provide the electrical connection through the circuit layer 10 without the conductive wires 70 and 71.

In some embodiments, the encapsulant 80 may be disposed between the circuit layer 10 and 20. In some embodiments, the encapsulant 80 may cover or encapsulate the dies 30 and 40, the elastic structures 51 and 52, and the leadframes 60. A portion of the leadframe 60 may protrude from the encapsulant 80, such that the leadfram 60 can connect the power module 1 to the external components. In some embodiments, the encapsulant 80 may be formed by a molding process. During molding, a mold may fix the circuit layers 10 and 20 to control the total height of the power module 1. With the flexibility provided by the elastic structures 51 and 52, the total height of the power module 1 can be controlled. In addition, the elastic structures 51 and 52 can also provide electric conductivity, thermal conductivity, and support.

In some embodiments, the encapsulant 80 may encapsulate the circuit layers 10 and 20. The conductive layers 13 and 23 may be exposed by the encapsulant 80. In some embodiments, the second surface 212 of the core substrate 21 may be exposed by the encapsulant 80. The encapsulant 80 may cover a lateral surface 213 of the core substrate 21. In another embodiment, the encapsulant 80 may partially cover the lateral surface 213. The second surface 212 of the core substrate 21 may be substantially coplanar with the top surface of the encapsulant 80. In some embodiments, the second surface 112 of the core substrate 11 may be exposed by the encapsulant 80. The encapsulant 80 may cover a lateral surface 113 of the core substrate 11. In another embodiment, the encapsulant 80 may partially cover the lateral surface 113. The second surface 112 of the core substrate 11 may be substantially coplanar with the bottom surface of the encapsulant 80.

The encapsulant 80 may be recessed at the edges. In some embodiments, the encapsulant 80 may have one or more dents 80r at the corners. Referring to FIG. 1, the dents 80r may be located at four corners/edges of the encapsulant 80. In some embodiments, the dents 80r may be recessed from the top surface of the encapsulant 80. The dents 80r may be recessed from the lateral surface of the encapsulant 80. The dents 80r may be apart from the circuit layers 10 and 20. In other words, the circuit layers 10 and 20 may not be exposed by the dents 80r. In some embodiments, the dents 80r may be resulted from the mold shape using in the molding process.

In some embodiments, the encapsulant 80 may include an epoxy resin, a molding compound (e.g., an epoxy molding compound, a molding compound including silica fillers, or other molding compound), a polyimide, a phenolic compound or material, a material including a silicone dispersed therein, or a combination thereof.

When the dies 30 and 40 have different thicknesses, the total height of the power module 1 can be controlled by compressing the elastic structures 51 and 52, and fixing the same with the encapsulant 80 to produce the power module 1. In such a case, the tolerance accumulation caused by stacked elements can be solved, and the total size of the power module 1 can be controlled and further decreased. In addition, the elastic structures 51 and 52 can also provide electric conductivity, thermal conductivity, and support. The dies 30 and 40 can have a thermal dissipation path upward through the elastic structures 51 and 52 to the circuit layer 20, and have another thermal dissipation path downward through the circuit layer 10. Therefore, the power module 1 can have a double-sided cooling arrangement.

FIG. 2A is a schematic diagram of an elastic structure 50a, in accordance with some embodiments of the present disclosure. Referring to FIG. 2A, the elastic structure 50a may be a spring, such as a coil spring or other suitable type. In some embodiments, the elastic structure 50a may have a spring constant that depends on the spring's material and construction. In some embodiments, the elastic structure 50a may have a first end 50a1 and a second end 50a2. In some embodiments, the elastic structure 50a may be a type of the elastic structures 51 and 52 of FIG. 1. In such a case, the first end 50a1 may connect to the circuit layer 20 and the second end 50a2 may connect to the die 30 or 40.

FIG. 2B is a schematic diagram of an elastic structure 50b, in accordance with some embodiments of the present disclosure. Referring to FIG. 2B, the elastic structure 50b may be an elastic reed or a clip. In some embodiments, the elastic structure 50b may be curved. For example, the elastic structure 50b may be folded. In some embodiments, the elastic structure 50b may have a first end 50b1 and a second end 50b2. In some embodiments, the elastic structure 50b may be a type of the elastic structures 51 and 52 of FIG. 1. In such a case, the first end 50b1 may connect to the circuit layer 20 and the second end 50b2 may connect to the die 30 or 40.

FIG. 2C(a) is a schematic diagram of an elastic structure 50c, in accordance with some embodiments of the present disclosure. FIG. 2C(b) is a cross-section of the elastic structure 50c of FIG. 2C(a), in accordance with some embodiments of the present disclosure. Referring to FIG. 2C(a) and 2C(b), the elastic structure 50c may be an elastic barrel. In some embodiments, the elastic structure 50c may have a first end 50c1 and a second end 50c2. In some embodiments, the elastic structure 50c may be a type of the elastic structures 51 and 52 of FIG. 1. In such a case, the first end 50c1 may connect to the circuit layer 20 and the second end 50c2 may connect to the die 30 or 40.

In some embodiments, the elastic structure 50c may include a housing 501, a pillar 502, and a spring 503. In some embodiments, the housing 501 may have a first portion 501a and a second portion 501b. The first portion 501a may be hollow, for example a cylinder, cube, cuboid, or other configuration. The second portion 501b may be a base. For example, the second portion 501b may be a plate connected to the first portion 501a. In some embodiments, the second portion 501b may connect to the die 30 or 40 of FIG. 1 though a soldering material (such as the soldering material 51h or 52h of FIG. 1).

In some embodiments, the housing 501 may have a cavity 501c and an opening 501p exposing the cavity 501c. In some embodiments, the opening 501p may face upward, i.e., the circuit layer 20 of FIG. 1. The opening 501p may be formed at the first portion 501a. The cavity 501c may be defined by the first portion 501a and the second portion 501b of the housing 501.

The spring 503 may be disposed within the housing 501 (i.e., the cavity 501c). In some embodiments, the spring 503 may be entirely within the cavity 501c. The pillar 502 may be disposed on the spring 503. In some embodiments, the spring 503 may support the pillar 502. In some embodiments, the pillar 502 may pass through the opening 501p of the housing 501 and partially within the cavity 501c of the housing 501. The pillar 502 may travel through the opening 501p of the housing 501. That is, the pillar 502 may be movable in one direction. For example, the pillar 502 may be movable upward or downward. In some embodiments, the housing 501 may be configured to define a travel or path of the pillar 502 (along with the spring 503). In some embodiments, the pillar 502 may be a cylinder, cube, cuboid, or other shape.

In some embodiments, the pillar 502 may include a protrusion 502t from the lateral surface of the pillar 502. The protrusion 502t may be configured to limit the pillar 502 from slipping out of the housing 501. In some embodiments, when the pillar 502 is a cylinder, the protrusion 502t may be a ring. In some embodiments, the size (i.e., the width or diameter) of the protrusion 502t may correspond to the inner size (i.e., the width or diameter) of the cavity 501c of the housing 501.

In some embodiments, the pillar 502 and the spring 503 may be regarded as an elastic element. The housing 501 may be configured to define a travel or a path of the elastic element, i.e., the pillar 502 and the spring 503. The elastic element, including the pillar 502 and the spring 503, may be a part of the thermal dissipation path of the dies 30 or 40.

The pillar 502 and the spring 503 may include a conductive material such as a metal or metal alloy. Examples of the conductive material include gold (Au), silver (Ag), aluminum (Al), copper (Cu), or an alloy thereof. The pillar 502 and the spring 503 may electrically connect the die 30 or 40 to the circuit layer 20 of FIG. 1. The pillar 502 and the spring 503 may be configured to dissipate heat from the die 30 or 40 of FIG. 1.

In some embodiments, the housing 501 may include a conductive material such as metal or metal alloy. Examples of the conductive material include gold (Au), silver (Ag), aluminum (Al), copper (Cu), or an alloy thereof. In some embodiments, the housing 501 (including the first portion 501a and second portion 501b) may be entirely conductive. That is, both of the first portion 501a and the second portion 501b may include a conductive material such as a metal or metal alloy. The housing 501 may electrically connect the die 30 or 40 to the circuit layer 20 of FIG. 1. The housing 501 may be configured to dissipate heat from the die 30 or 40 of FIG. 1.

In another embodiment, t he first portion 501a of the housing 501 may include an insulating material. In such a case, the electrical connection of the elastic structure 50c may be merely through the pillar 502, the spring 503, and the second portion 501b of the housing 501. The insulating portion 501a of the housing 501 may define the travel or path of the elastic element, i.e., the pillar 502 and the spring 503.

In some embodiments, the elastic structures 51 and 52 of FIG. 1 may be the same as elastic structure 50a, 50b, or 50c. In some embodiments, the type of the elastic structures 51 and 52 may be the same with different elastic modulus. For example, the elastic structures 51 and 52 may both be elastic barrels with different sizes or elastic modulus. In another embodiment, the elastic structures 51 and 52 may be different types. For example, the elastic structure 51 may be a spring, and the elastic structure 52 may be an elastic reed.

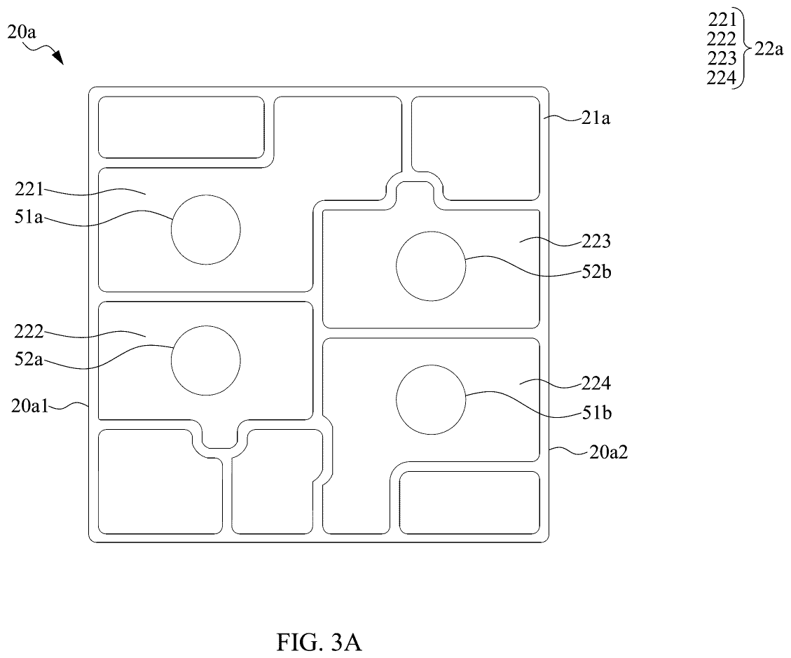

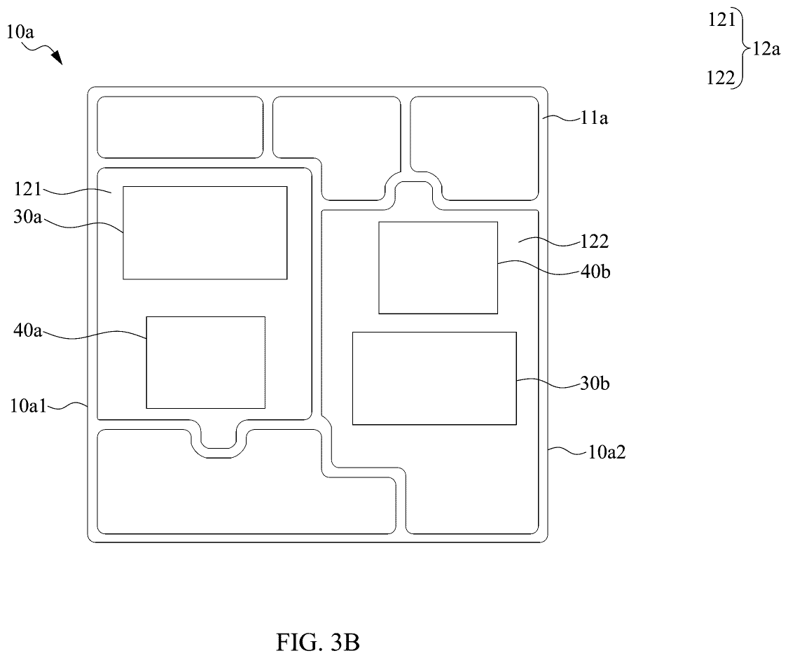

FIG. 3A is a bottom view of a circuit layer 20a of a power module, in accordance with some embodiments of the present disclosure. FIG. 3A shows an exemplary pattern of the circuit layer 20 of FIG. 1. Referring to FIG. 3A, the circuit layer 20a includes the core substrate 21a and the patterned conductive layer 22a. The patterned conductive layer 22a may include one or more portions 221, 222, 223, and 224. The portions 221, 222, 223, and 224 of the conductive layers 22a may be spaced apart from each other. In some embodiments, the portions 221, 222, 223, and 224 may be round, square, rectangular, or irregular. The shapes of the portions 221, 222, 223, and 224 may be identical or different.

Referring to FIG. 3A, the portions 221 and 222 may be located at a side 20a1, and the portions 223 and 224 may be located at a side 20a2 opposite to the side 20a1. In some embodiments, the portions 221, 222, 223, and 224 of the conductive layer 22a may connect to one or more elastic structures, such that the heat generated by the dies (not shown) could be dissipated to the conductive layer 22a through the elastic structures. In addition, the dies may be electrically connected to the conductive layer 22a through the elastic structures.

In some embodiments, the portion 221 may connect to an elastic structure 51a. The portion 222 may connect to an elastic structure 52a. The portion 223 may connect to an elastic structure 52b. The portion 224 may connect to an elastic structure 51b. The elastic structures 51a and 51b may be similar to the elastic structure 51 of FIG. 1. The elastic structures 52a and 52b may be similar to the elastic structure 52 of FIG. 1.

In some embodiments, the portions of the conductive layer 22a may be connected through electrical connectors (not shown), such as bonding wire, leadframe, other conductive structures, or a combination thereof.

FIG. 3B is a top view of a circuit layer 10a of the power module 1 of FIG. 1, in accordance with some embodiments of the present disclosure. FIG. 3B shows an exemplary pattern of the circuit layer 10 of FIG. 1. Referring to FIG. 3B, the circuit layer 10a includes the core substrate 11a and the patterned conductive layer 12a. The patterned conductive layer 12a may include one or more portions 121 and 122. The portions 121 and 122 of the conductive layers 12a may be spaced apart from each other. In some embodiments, the portions 121 and 122 may be round, square, rectangular, or irregular. The shapes of the portions 121 and 122 may be identical or different.

Referring to FIG. 3B, the portion 121 may be located at a side 10a1, and the portion 122 may be located at a side 10a2 opposite to the side 10a1. In some embodiments, the portions 121 and 122 of the conductive layer 12a may connect to one or more dies 30a, 30b, 40a, and 40b, such that the heat generated by the dies 30a, 30b, 40a, and 40b could be dissipated to the conductive layer 12a. In addition, the dies 30a, 30b, 40a, and 40b may be electrically connected to the conductive layer 12a. In some embodiments, the portion 121 may connect to dies 30a and 40a. The dies 30a and 40a may be electrically connected through the portion 121 of the conductive layer 12a. In some embodiments, the portion 122 may connect to the dies 30b and 40b. The dies 30b and 40b may be electrically connected through the portion 122 of the conductive layer 12a. The dies 30a and 30b may be similar to the die 30 of FIG. 1. The dies 40a and 40b may be similar to the die 40 of FIG. 1.

In some embodiments, the portions of the conductive layer 12a may be connected through electrical connectors (not shown), such as bonding wire, leadframe, other conductive structures, or a combination thereof.

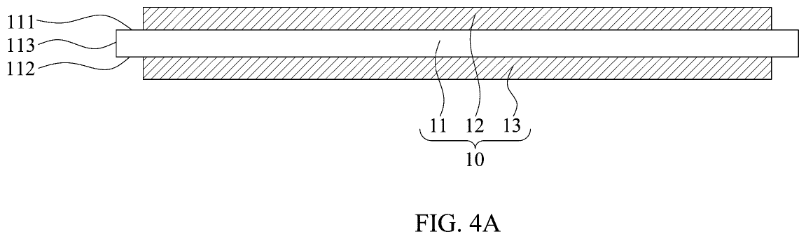

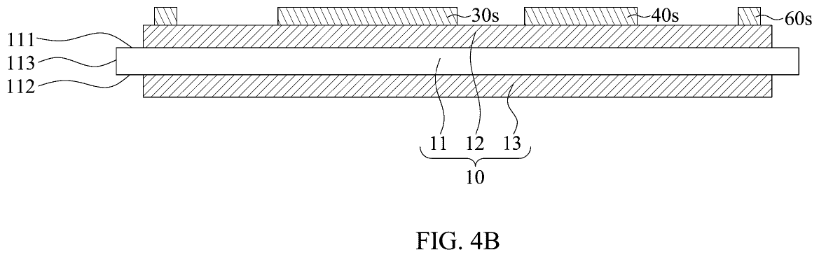

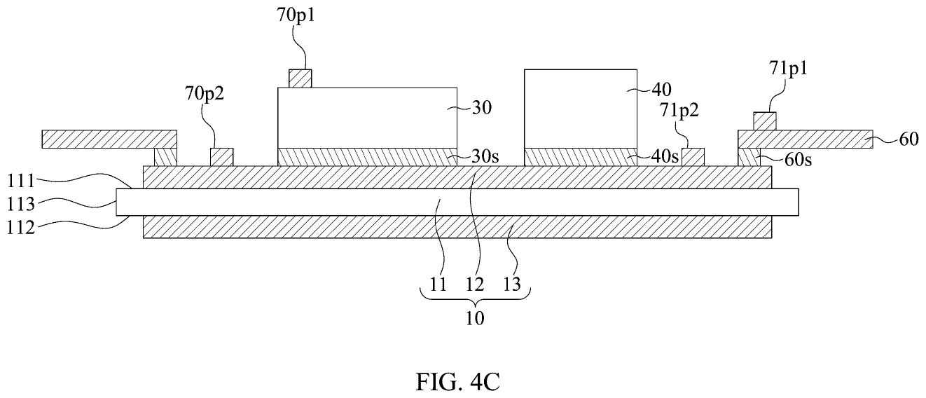

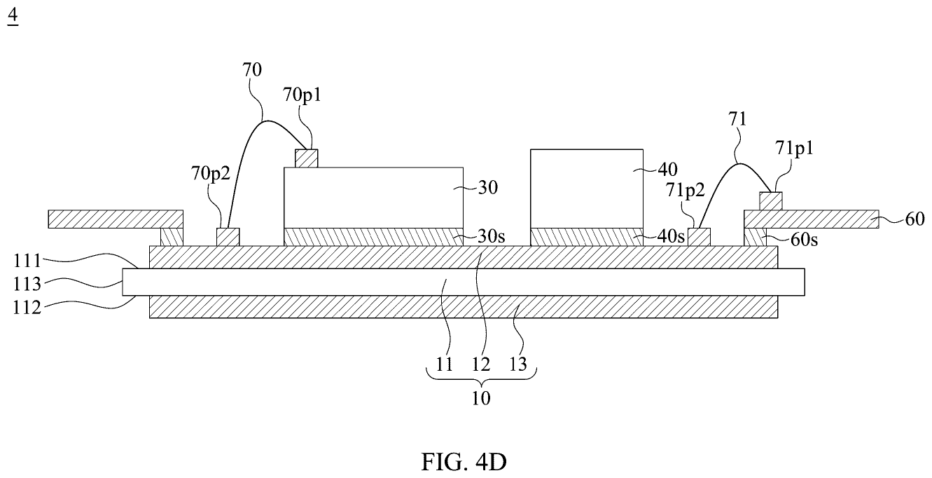

FIG. 4A, FIG. 4B, FIG. 4C, and FIG. 4D illustrate one or more operations of a method for manufacturing a power module 1, in accordance with some embodiments of the present disclosure.

Referring to FIG. 4A, a circuit layer 10 is provided. In some embodiments, the circuit layer 10 may include a core substrate 11 and two conductive layers 12 and 13. The core substrate 11 may be sandwiched between the conductive layers 12 and 13. The core substrate 11 may have a first surface 111 and a second surface 112 opposite to the first surface 111. The conductive layer 12 may be disposed on the first surface 111 of the circuit layer 10. The conductive layer 13 may be disposed on the second surface 112 of the circuit layer 10.

Referring to FIG. 4B, soldering materials 30s, 40s, and 60s are attached to the conductive layer 12 of the circuit layer 10. In some embodiments, the soldering materials 30s and 40s may be applied on the conductive layer 12 based on the location that dies 30 and 40 to be placed. The soldering materials 60s may be applied on the conductive layer 12 based on the location that leadframes 60 to be placed.

Referring to FIG. 4C, the dies 30 and 40 are disposed on and attached to the soldering materials 30s and 40s, respectively, and the leadframes 60 are disposed on and attached to the soldering materials 30s and 40s. In some embodiments, conductive pads 70p1, 70p2, 71p1, and 71p2 are formed. The conductive pad 70p1 may be disposed on the top surface of the die 30. The conductive pad 70p2 may be disposed on the top surface of the conductive layer 12 of the circuit layer 10 beside the die 30. The conductive pad 71p1 may be disposed on the leadframe 60. The conductive pad 71p2 may be disposed on the top surface of the conductive layer 12 of the circuit layer 10 beside the leadframe 60. In some embodiments, after the dies 30 and 40 and leadframes 60 are placed on the soldering materials 30s, 40s, and 60s, a heat treatment, such as vacuum soldering, may be performed, such that the dies 30 and 40 and leadframes 60 can be fixed to the conductive layer 12 through the soldering materials 30s, 40s, and 60s.

Referring to FIG. 4D, one or more conductive wires 70 and 71 are formed. The conductive wire 70 may electrically connect the die 30 to the circuit layer 10. The conductive wire 70 may be bonded to the top surface of the die 30 through the conductive pad 70p1. The conductive wire 70 may be bonded to the top surface of the conductive layer 12 of the circuit layer 10 through the conductive pad 70p2.

In some embodiments, the conductive wire 71 may electrically connect the leadframe 60 to the circuit layer 10. The conductive wire 71 may be bonded to the leadframe 60 through the conductive pad 71p1. The conductive wire 71 may be bonded to the top surface of the conductive layer 12 of the circuit layer 10 through the conductive pad 71p2.

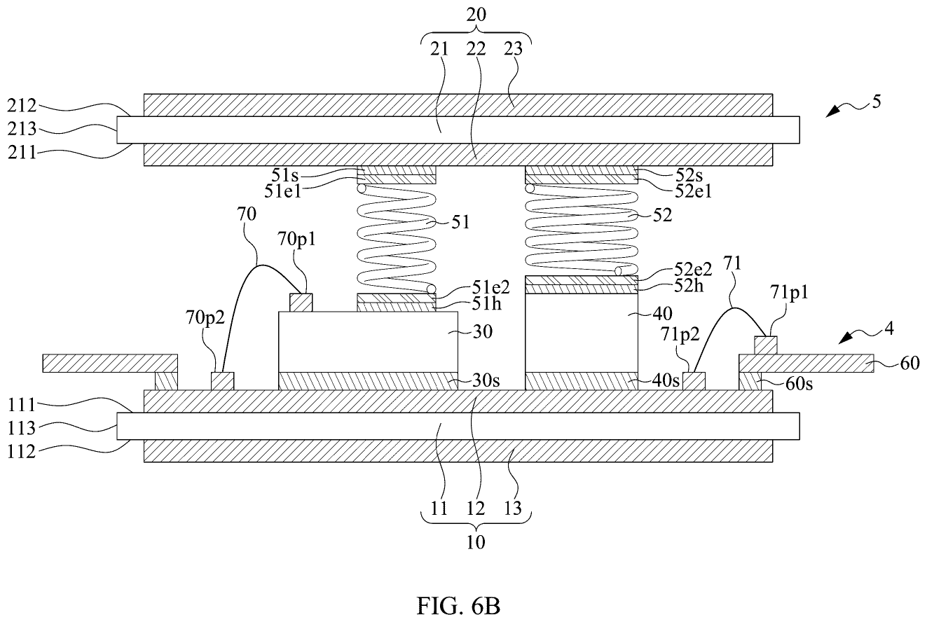

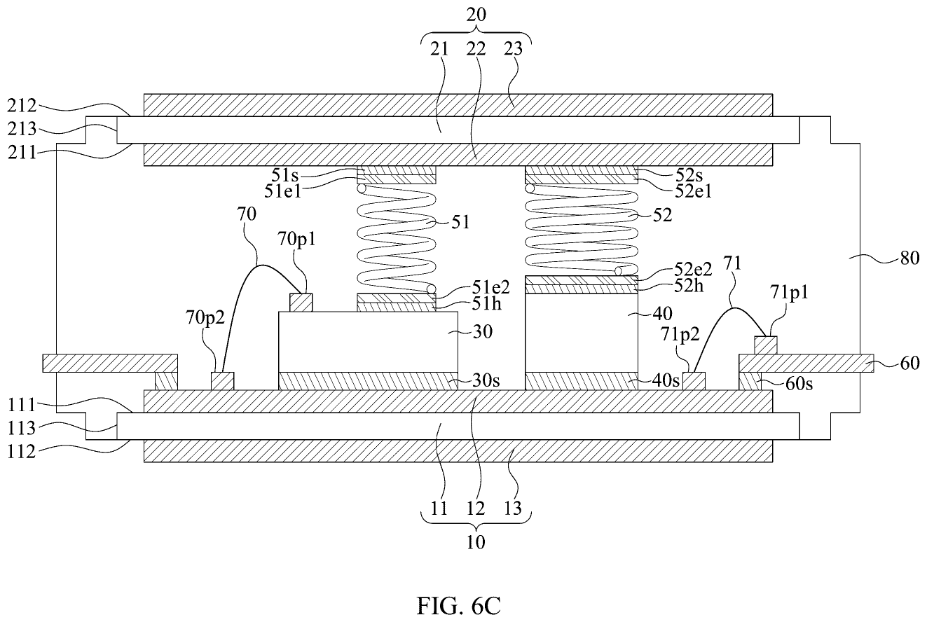

After the conductive wires 70 and 71 are formed, a first semi-product 4 may be obtained for subsequent processes of FIG. 6A, FIG. 6B, and FIG. 6C.

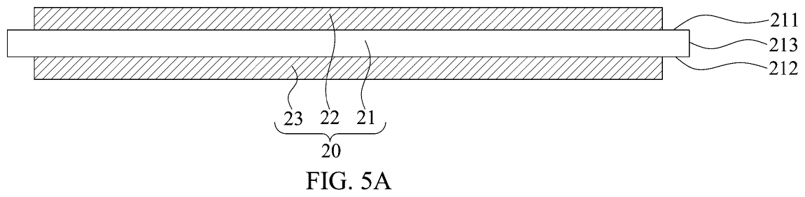

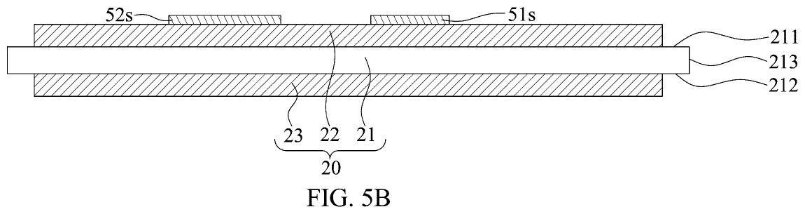

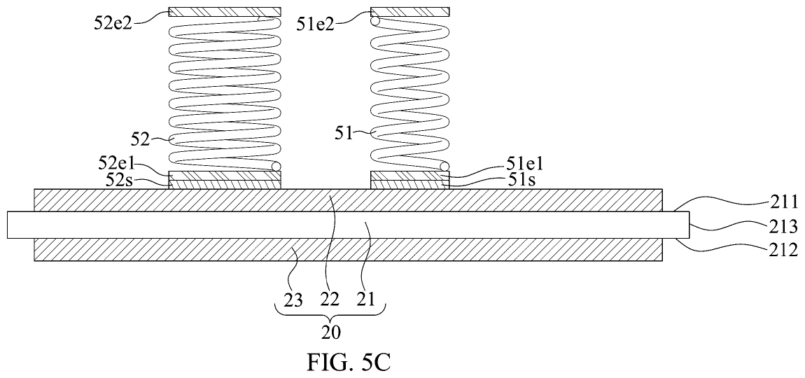

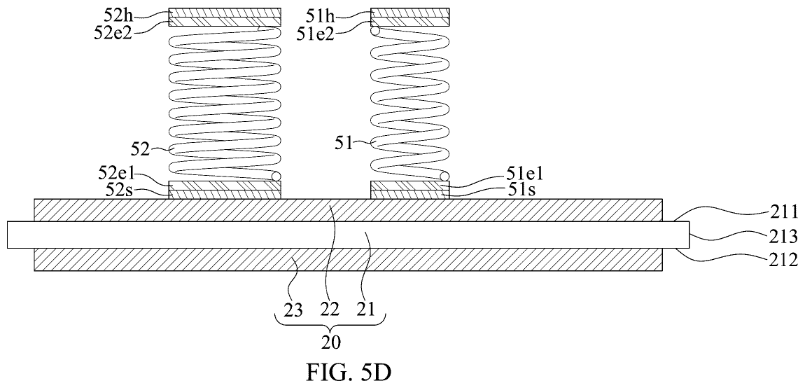

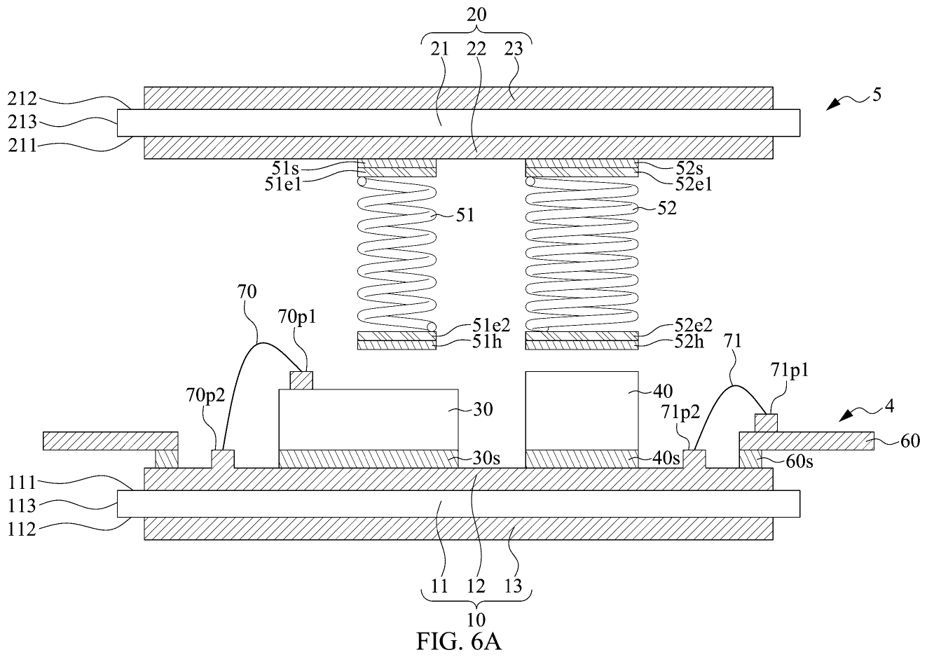

FIG. 5A, FIG. 5B, FIG. 5C, and FIG. 5D illustrate one or more operations of a method for manufacturing a power module 1, in accordance with some embodiments of the present disclosure.

Referring to FIG. 5A, a circuit layer 20 is provided. In some embodiments, the circuit layer 20 may include a core substrate 21 and two conductive layers 22 and 23. The core substrate 21 may be sandwiched between the conductive layers 22 and 23. The core substrate 21 may have a first surface 211 and a second surface 212 opposite to the first surface 211. The conductive layer 22 may be disposed on the first surface 211 of the circuit layer 20. The conductive layer 23 may be disposed on the second surface 212 of the circuit layer 20.

Referring to FIG. 5B, soldering materials 51s and 52s are attached to the conductive layer 22 of the circuit layer 20. In some embodiments, the soldering materials 51s and 52s may be applied on the conductive layer 22 based on the location in which elastic structures 51 and 52 are to be placed.

Referring to FIG. 5C, the elastic structures 51 and 52 are disposed on and attached to the soldering materials 51s and 52s, respectively. In some embodiments, the elastic structure 51 may be attached to the soldering material 51s through the connector 51e1. The elastic structure 51 may have the connector 51e2 opposite to the connector 51e1. In some embodiments, the elastic structure 52 may be attached to the soldering material 52s through the connector 52e1. The elastic structure 52 may have the connector 52e2 opposite to the connector 52e1. In some embodiments, after the elastic structures 51 and 52 are placed on the soldering materials 51s and 52s, a heat treatment, such as vacuum soldering, may be performed, such that the connectors 51e1 and 52e1 can be bonded to the conductive layer 12 through the soldering materials 51s and 52s, and thus the elastic structures 51 and 52 can be fixed to the conductive layer 12.

Referring to FIG. 5D, soldering materials 51h and 52h are placed on and attached to the elastic structures 51 and 52, respectively. In some embodiments, the soldering materials 51h and 52h may be placed on the connectors 51e2 and 52e2, respectively. In some embodiments, the soldering materials 51h and 52h may be configured to attach the elastic structures 51 and 52 to the dies 30 and 40. After the soldering materials 51h and 52h are placed on the elastic structures 51 and 52, a heat treatment, such as vacuum soldering, may be performed, such that the soldering materials 51h and 52h can be bonded to the connectors 51e2 and 52e2 of the elastic structures 51 and 52. In some embodiments, the heat treatment of the soldering materials 51s and 52s may be performed with the soldering materials 51h and 52h. That is, the heat treatment of the soldering materials 51s and 52s may be performed after the soldering materials 51h and 52h are attached to the elastic structures 51 and 52.

After the heat treatment of the soldering materials 51h and 52h is performed, a second semi-product 5 may be obtained for subsequent processes of FIG. 6A, FIG. 6B, and FIG. 6C.

FIG. 6A, FIG. 6B, and FIG. 6C illustrate one or more operations of a method for manufacturing a power module 1, in accordance with some embodiments of the present disclosure.

Referring to FIG. 6A, the first semi-product 4 is provided and the second semi-product 5 is disposed upside down on the first semi-product 4. That is, the second semi-product 5 is stacked on the first semi-product 4. The elastic structure 51 may correspond to the die 30, and the elastic structure 52 may be correspond to the die 40. In some embodiments, the elastic structure 52 may be aligned with the die 40. In some embodiments, the circuit layer 20 may be aligned with the circuit layer 10.

Referring to FIG. 6B, soldering materials 51h and 52h are placed on and attached to the dies 30 and 40, respectively. In some embodiments, the soldering materials 51h and 52h may attach the elastic structures 51 and 52 to the dies 30 and 40. In some embodiments, a heat treatment, such as vacuum soldering, may be performed, such that the soldering materials 51h and 52h can be bonded to the dies 30 and 40.

Referring to FIG. 6C, the second semi-product 5 and the first semi-product 4 may be clamped, and thus the elastic structures 51 and 52 are compressed. In some embodiments, the second semi-product 5 and the first semi-product 4 may be fixed by a mold. Then, the encapsulant 80 may be formed by a molding process. The encapsulant 80 may encapsulate and protect the circuit layers 10 and 20, the dies 30 and 40, the elastic structures 51 and 52, the conductive wires 70 and 71, and the leadframes 60. Then, a power module 1 as described and illustrated with reference to FIG. 1 is formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A power module, comprising:
a first die having an upper surface;
a second die adjacent to the first die and having an upper surface at an elevation different from the upper surface of the first die;
a circuit structure disposed over the first die and the second die and having a surface; and
an elastic structure connecting the first die and the second die to the circuit structure and configured to keep the surface of the circuit structure being substantially horizontal.

2. The power module of claim 1, wherein one of the first die and the second die includes a transistor, and the other one includes a diode.

3. The power module of claim 1, wherein an area of the first die is different from an area of the second die from a top view.

4. The power module of claim 1, wherein a thickness of the first die is different from a thickness of the second die.

5. The power module of claim 1, wherein the surface of the circuit structure is substantially parallel to the upper surfaces of the first die and the second die.

6. The power module of claim 5, wherein the surface of the circuit structure faces upward and away from the first die and the second die.

7. The power module of claim 1, wherein the elastic structure comprises:
a first elastic element connected to the first die; and
a second elastic element connected to the second die and separated from the first elastic element.

8. The power module of claim 7, wherein a width of the first elastic element is different from a width of the second elastic element in a side view.

9. The power module of claim 7, further comprising an encapsulant encapsulating the first elastic element and the second elastic element, wherein a first portion of the encapsulant is between the first elastic element and the second elastic element.

10. The power module of claim 9, wherein the first elastic element forms a space, wherein a second portion of the encapsulant is disposed within the space.

11. A power module, comprising:
a power die;
a circuit structure disposed over the power die and configured to provide a thermal dissipated channel for the power die; and
a elastic structure electrically connecting the power die to the circuit structure and including an housing and an elastic element within the housing.

12. The power module of claim 11, wherein the elastic structure further comprises a pillar connecting the elastic element to the circuit structure, wherein the pillar passes through an opening of the housing and partially within the housing.

13. The power module of claim 12, wherein the pillar has a protrusion from a lateral surface of the pillar configured to limit the pillar from slipping out of the housing.

14. The power module of claim 11, wherein the housing includes an insulating portion and a conductive portion, wherein the insulating portion is configured to define a moving path of the elastic element, and the conductive portion electrically connects the elastic element to the power die.

15. A power module, comprising:
a first power die;
a second power die beside the first power die;
a circuit layer disposed on the first power die and the second power die;
a first elastic structure disposed between the circuit layer and the first power die, wherein the first elastic structure has a first elastic modulus; and
a second elastic structure disposed between the circuit layer and the second power die,
wherein the second elastic structure has a second elastic modulus different from the first elastic modulus.

16. The power module of claim 15, wherein the circuit layer comprises:
a core substrate having a first surface and a second surface opposite to the first surface;
a first conductive layer disposed on the first surface of the core substrate; and
a second conductive layer disposed on the second surface of the core substrate.

17. The power module of claim 16, further comprising an encapsulant encapsulating the core substrate and the first conductive layer.

18. The power module of claim 17, wherein the encapsulant covers a lateral surface of the core substrate.

19. The power module of claim 15, wherein the first elastic structure includes a spring, an elastic reed, or an elastic barrel.

20. The power module of claim 15, wherein a first length of the first elastic structure is greater than a second length of the second elastic structure.
